(19) United States
(12) Patent Application Publication
(10) Pub. No.: US 2014/0036612 A1
(43) Pub. Date: Feb. 6, 2014

(54) BTI-Independent Source Biasing of Memory Arrays

(71) Applicant: Dharmendra Kumar Rai, Mau (IN)

(72) Inventor: Dharmendra Kumar Rai, Mau (IN)

(73) Assignee: LSI CORPORATION, Milpitas, CA (US)

(21) Appl. No.: 13/567,134

(22) Filed: Aug. 6, 2012

(51) Int. Cl. G11C 5/14

(52) U.S. Cl. 365/227

(57) ABSTRACT

A memory device having an array of memory cells and BTI-independent bias circuitry for controlling the bias voltage level of a source node of the array. The bias circuitry has an n-type transistor and a p-type transistor connected in parallel between ground and the source node. The bias circuitry also has circuitry for controlling the n-type and p-type transistors such that the memory device can be selectively configured in any of an active mode (where the source node is driven towards ground such that the array can be accessed), a low-leakage-current light sleep mode (where the source node is driven towards an intermediate, data-retention voltage level such that the array cannot be accessed but will retain data), and an even-lower-leakage-current shutdown mode (where the source node is driven towards the power supply voltage level such that the array cannot be accessed and cannot retain data).

### BACKGROUND

This section introduces aspects that may help facilitate a better understanding of the invention. Accordingly, the statements of this section are to be read in this light and are not to be understood as admissions about what is prior art or what is not prior art.

When a memory device having an array of SRAM (static random-access memory) cells is to be accessed (e.g., data written to or read from one or more rows of memory cells in the array), the memory device is configured in a so-called active mode with (i) the power supply voltage VDDC applied to the drain nodes of certain p-type MOS (metal-oxide semiconductor) transistors in each memory cell and (ii) a lower, ground voltage applied to the source nodes VSSC of certain n-type MOS transistors in each memory cell to enable these transistors to be turned on and off with appropriate control voltages applied to their gates.

In order to reduce power consumption due to leakage currents through the memory cells, when access to such a memory device is not needed, it is known to bias the source nodes VSSC of such memory cells to an appropriate intermediate, data-retention voltage level between ground and VDDC to place the memory device into a light sleep mode in which the memory array cannot be accessed, but will retain data previously stored therein. Bias circuitry is provided to control the application and removal of such source bias voltages to enable the memory device to be selectively configured in either its light sleep mode or its active mode.

Bias temperature instability (BTI) is a phenomenon in which the threshold voltage VT of a transistor changes over time. In order for bias circuitry for a memory device to operate correctly over the lifetime of the memory device, it is important that such bias circuitry be independent of the effects of BTI on the threshold voltages VT of transistors used to implement that bias circuitry.

### BRIEF DESCRIPTION OF THE DRAWINGS

Other aspects, features, and advantages of the present invention will become more fully apparent from the following detailed description, the appended claims, and the accompanying drawings in which like reference numerals identify similar or identical elements.

FIG. 1 shows a simplified schematic diagram of a memory device according to one embodiment of the disclosure;

FIG. 2 shows a simplified schematic diagram of the memory device of FIG. 1 configured in its active mode;

FIG. 3 shows a simplified schematic diagram of the memory device of FIG. 1 configured in its light sleep mode; and

FIG. 4 shows a simplified schematic diagram of the memory device of FIG. 1 configured in its shutdown mode.

### DETAILED DESCRIPTION

FIG. 1 shows a simplified schematic diagram of a memory device 100 according to one embodiment of the disclosure. As shown in FIG. 1, memory device 100 comprises SRAM core 102, representing an array of memory cells (not shown) arranged in rows and columns, and bias circuitry 104 designed to control the level of a bias voltage applied to the source node VSSC of SRAM core 102 to selectively configure memory device 100 into either its light sleep mode or its active mode. In this particular embodiment, memory device 100 also has a shutdown mode in which the memory cells are source biased such that leakage current is further reduced, but at the expense of the memory cells being unable to retain data previously stored therein.

Although not shown in FIG. 1, memory device 100 has other circuitry (e.g., row drivers and column drivers and sensors) that would be known to those skilled in the art. Also not shown in FIG. 1 is a memory controller that controls the voltage levels of control signals (i.e., SD, LSD, SDB, and LSDB) that are applied to the gates of certain transistors (i.e., M2-M5 and M12-M15) in bias circuitry 104. Depending on the particular implementation, that memory controller may be implemented on the same integrated circuit as memory device 100 or external to that integrated circuit.

As represented in FIG. 1, bias circuitry 104 has an n-type transistor M1 configured in parallel with a p-type transistor M11 between ground and the source node VSSC of SRAM core 102. In addition, bias circuitry 104 includes a first set of transistors (i.e., transistors M2-M5) for controlling the gate voltage WUT applied to n-type transistor M1 and a second set of circuitry (i.e., transistors M12-M15) for controlling the gate voltage WUB applied to p-type transistor M11. Together, the states of n-type transistor M1 and p-type transistor M11 determine the bias voltage level of the source node VSSC to control whether memory device 100 is configured in its active mode, its light sleep mode, or its shutdown mode.

Table I provides a summary of the three operating modes (active, light sleep, and shutdown) for a particular implementation of memory device 100 in which the power supply voltage VDDC is about 500 mV and the data-retention source bias voltage level is about 150 mV.

TABLE I
MEMORY DEVICE OPERATING MODES

| SD | LSD | VSSC Level | Mode | Transistor State |
|---|---|---|---|---|
| 0 | 0 | ~10 mV | Active | M2, M3, M12, M15 OFF; |
| | | | | M4, M5, M13, M14 ON |
| 0 | 1 | ~150 mV | Light Sleep | M3, M5, M13, M15 OFF; |
| | | | | M2, M4, M12, M14 ON |
| 1 | 0 | ~500 mV | Shutdown | M2, M4, M12, M14 OFF; |
| | | | | M3, M5, M13, M15 ON |

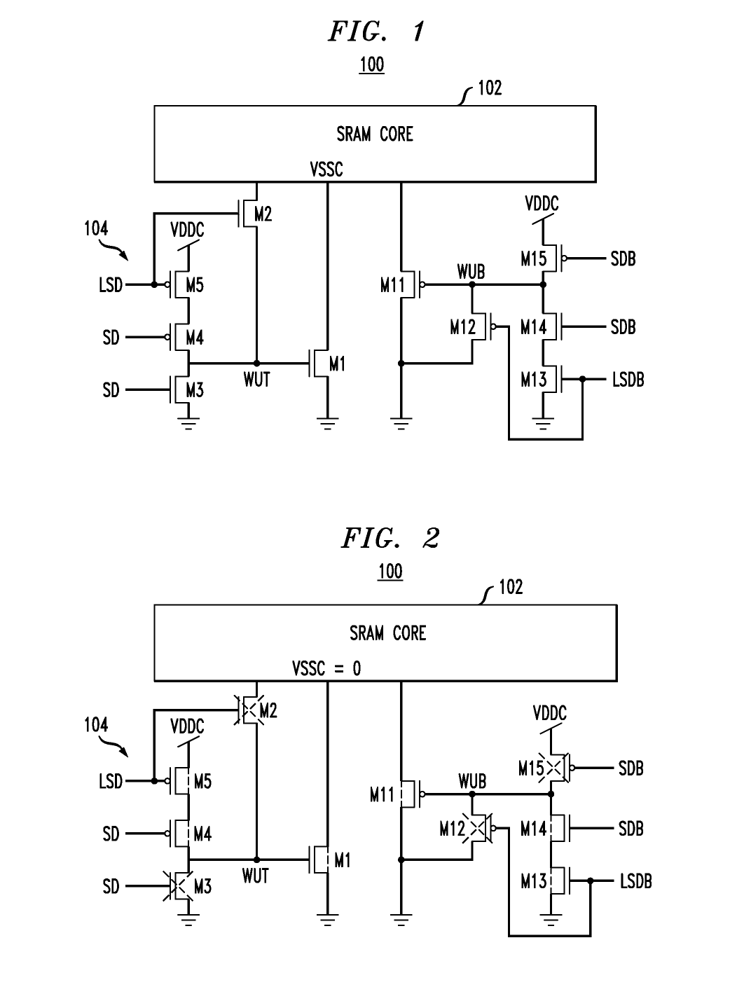

FIG. 2 shows a simplified schematic diagram of memory device 100 configured in its active mode. As indicated in both FIG. 2 and Table I, when control signals SD and LSD are both at logic 0 (i.e., low voltage in this implementation), such that corresponding inverted control signals SDB and LSDB are both at logic 1 (i.e., high voltage in this implementation), n-type transistors M2 and M3 and p-type transistors M12 and M15 are off, while p-type transistors M4 and M5 and n-type transistors M13 and M14 are on. In this mode, transistors Ml and Ml l are both on, and the source node VSSC is driven towards ground (e.g., about 10 mV), which enables access to the memory cells of SRAM core 102.

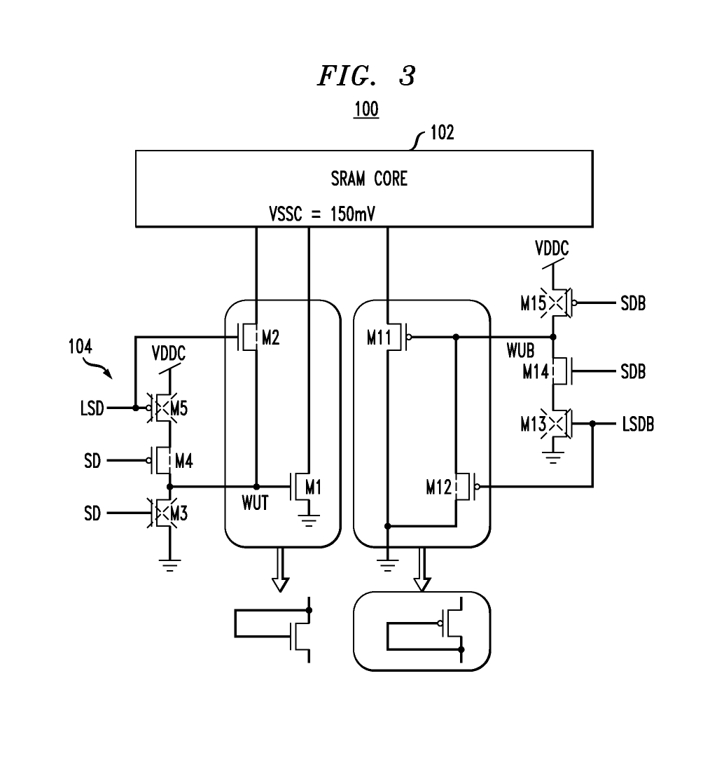

FIG. 3 shows a simplified schematic diagram of memory device 100 configured in its light sleep mode. As indicated in both FIG. 3 and Table I, when control signal SD is at logic 0 and control signal LSD is at logic 1, transistors M3, M5, M13, and M15 are off, while transistors M2, M4, M12, and M14 are on. In this mode, transistors M1 and M11 are diode connected, which drives the source node VSSC towards the intermediate, data-retention voltage level of about 150 mV, which, in turn, prevents access to the memory cells of SRAM core 102, but enables those memory cells to retain data previously stored therein and reduces leakage current through the transistors in SRAM core 102 compared to the leakage current of the active mode.

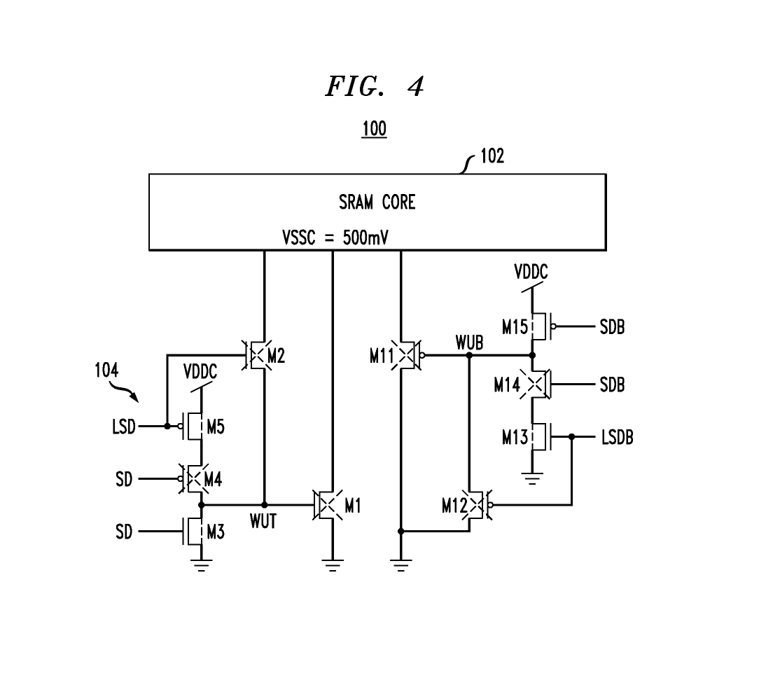

FIG. 4 shows a simplified schematic diagram of memory device 100 configured in its shutdown mode. As indicated in both FIG. 4 and Table I, when control signal SD is at logic 1 and control signal LSD is at logic 0, transistors M2, M4, M12, and M14 are off, while transistors M3, M5, M13, and M15 are on. In this mode, transistors M1 and M11 are off, which drives the source node VSSC towards the power supply voltage of about 500 mV, which, in turn, prevents access to the memory cells of SRAM core 102 and prevents those memory cells from retaining data previously stored therein, but further reduces leakage current through the transistors in SRAM core 102 compared to the leakage currents of both the active mode and the light sleep mode. Although not shown in FIG. 4, memory device 100 has other circuitry that drives VSSC towards VDDC, when memory device 100 is configured in its shutdown mode.

Bias temperature instability (BTI) causes the threshold voltage VT of n-type MOS transistors to decrease over time, while BTI causes the threshold voltage VT of p-type MOS transistors to increase over time. Because transistor M1 is an n-type transistor and transistor M11 is a p-type transistor, BTI effects that would tend to decrease the threshold voltage VT of n-type transistor M1 over time, would tend to increase the threshold voltage VT of p-type transistor M11 over time. Since transistors M1 and M11 are configured in parallel between ground and the source node VSSC, the net effect of these countervailing BTI dependencies is that the bias voltage level supplied in parallel to source node VSSC from both transistors for a given operating mode is substantially independent of BTI. Thus, for the exemplary implementation of Table I, for the active mode, VSSC will remain at about 15 mV over the operating lifetime of the memory device. Similarly, for the light sleep mode, VSSC will remain at about 150 mV for that same operating lifetime. And lastly, for the shutdown mode, VSSC will remain at about 500 mV for that same operating lifetime. Furthermore, because the source bias voltage is supplied by the two parallel transistors M1 and M11, the sizes of those transistors can be about half the size of the n-type transistor typically used in single-transistor solutions. As a result, the invention can be implemented without significantly impacting layout area.

Although the invention has been described in the context of memory device 100 having a power supply voltage of about 500 mV and a data-retention source bias voltage level of about 150 mV, those skilled in the art will understand that the invention can be implemented for memory devices having greater or lesser power supply voltages and/or greater or lesser data-retention source bias voltage levels.

Although the invention has been described in the context of bias circuitry 104 having a particular architecture for the first and second sets of transistors used to control the gate voltages applied to the parallel-connected n-type and p-type transistors M1 and M11, those skilled in the art will understand that there are other possible transistor architectures can be deployed to configure n-type and p-type transistors connected in parallel to control the bias voltage applied to source node VSSC.

In one embodiment, the claimed apparatus is a memory device. In another embodiment, the claimed apparatus is a larger system, such as a computer, a cellular telephone, or any other suitable consumer electronics product, that includes the memory device along with other electronic components. The present invention may be implemented as (analog, digital, or a hybrid of both analog and digital) circuit-based processes, including possible implementation as a single integrated circuit (such as an ASIC or an FPGA), a multi-chip module, a single card, or a multi-card circuit pack. As would be apparent to one skilled in the art, various functions of circuit elements may also be implemented as processing blocks in a software program. Such software may be employed in, for example, a digital signal processor, micro-controller, general-purpose computer, or other processor.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

Also, for purposes of this description, it is understood that all gates are powered from a fixed-voltage power domain (or domains) and ground unless shown otherwise. Accordingly, all digital signals generally have voltages that range from approximately ground potential to that of one of the power domains and transition (slew) quickly. However and unless stated otherwise, ground may be considered a power source having a voltage of approximately zero volts, and a power source having any desired voltage may be substituted for ground. Therefore, all gates may be powered by at least two power sources, with the attendant digital signals therefrom having voltages that range between the approximate voltages of the power sources.

Signals and corresponding nodes or ports may be referred to by the same name and are interchangeable for purposes here.

Transistors are typically shown as single devices for illustrative purposes. However, it is understood by those with skill in the art that transistors will have various sizes (e.g., gate width and length) and characteristics (e.g., threshold voltage, gain, etc.) and may consist of multiple transistors coupled in parallel to get desired electrical characteristics from the combination. Further, the illustrated transistors may be composite transistors.

As used in this specification and claims, the term “output node” refers generically to either the source or drain of a metal-oxide semiconductor (MOS) transistor device (also referred to as a MOSFET), and the term “control node” refers generically to the gate of the MOSFET. Similarly, as used in the claims, the terms “source,” “drain,” and “gate” should be understood to refer either to the source, drain, and gate of a MOSFET or to the emitter, collector, and base of a bi-polar device when the present invention is implemented using bi-polar transistor technology.

Unless explicitly stated otherwise, each numerical value and range should be interpreted as being approximate as if the word “about” or “approximately” preceded the value of the value or range.

It will be further understood that various changes in the details, materials, and arrangements of the parts which have been described and illustrated in order to explain the nature of this invention may be made by those skilled in the art without departing from the scope of the invention as expressed in the following claims.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

What is claimed is:

1. Apparatus having a memory device comprising:
an array (e.g., 102) of memory cells having a source node (e.g., VSSC); and
bias circuitry (e.g., 104) configured to control a bias voltage level applied to the source node of the array, wherein the bias circuitry comprises an n-type first transistor (e.g., M1) and a p-type second transistor (e.g., M11) connected in parallel between ground and the source node.

2. The invention of claim 1, wherein the bias circuitry enables the memory device to be selectively configured into any one of:
an active mode in which the array of memory cells can be accessed;
a light sleep mode in which the array of memory cells cannot be accessed, but will retain data previously stored therein; and
a shutdown mode in which the array of memory cells cannot be accessed and will not retain the data previously stored therein.

3. The invention of claim 2, wherein:
in the active mode, the first and second transistors are both on, such that the source node is driven towards ground;
in the light sleep mode, the first and second transistors are diode-connected, such that the source node is driven towards an intermediate, data-retention voltage level between ground and a power supply voltage level (e.g., VDDC) for the memory device; and
in the shutdown mode, the first and second transistors are both off, such that the source node is driven towards the power supply voltage level.

4. The invention of claim 3, wherein the bias circuitry further comprises:
a first set of transistors (e.g., M2-M5) connected to control gate voltage (e.g., WUT) applied to the first transistor; and
a second set of transistors (e.g., M12-M15) connected to control gate voltage (e.g., WUB) applied to the second transistor.

5. The invention of claim 4, wherein:
the first set of transistors comprises:
an n-type third transistor (e.g., M2) connected between the source node and the gate of the first transistor;
a p-type fourth transistor (e.g., M5) and a p-type fifth transistor (e.g., M4) configured in series between the power supply voltage level and the gate of the first transistor; and
an n-type sixth transistor (e.g., M3) configured between the gate of the first transistor and ground; and
the second set of transistors comprises:
a p-type seventh transistor (e.g., M12) connected between the gate of the second transistor and ground;
an n-type eighth transistor (e.g., M14) and an n-type ninth transistor (e.g., M13) configured in series between the gate of the second transistor and ground; and
a p-type tenth transistor (e.g., M15) configured between the power supply voltage level and the gate of the second transistor.

6. The invention of claim 5, wherein the first and second sets of transistors are configured such that:
a first control signal (e.g., SD) is applied to the gates of the fifth and sixth transistors;
a second control signal (e.g., LSD) is applied to the gates of the third and fourth transistors;
an inverted version of the first control signal (e.g., SDB) is applied to the gates of the eighth and tenth transistors; and
an inverted version of the second control signal (e.g., LSDB) is applied to the gates of the seventh and ninth transistors.

7. The invention of claim 1, wherein the apparatus is the memory device.

8. The invention of claim 1, wherein the apparatus is a consumer electronics product comprising the memory device and one or more other electronic components.

9. An integrated circuit having a memory device comprising:
an array (e.g., 102) of memory cells having a source node (e.g., VSSC); and
bias circuitry (e.g., 104) configured to control a bias voltage level applied to the source node of the array, wherein the bias circuitry comprises an n-type first transistor (e.g., M1) and a p-type second transistor (e.g., M11) connected in parallel between ground and the source node.

10. The invention of claim 9, wherein the bias circuitry enables the memory device to be selectively configured into any one of:
an active mode in which the array of memory cells can be accessed;
a light sleep mode in which the array of memory cells cannot be accessed, but will retain data previously stored therein; and
a shutdown mode in which the array of memory cells cannot be accessed and will not retain the data previously stored therein.

11. The invention of claim 10, wherein:
in the active mode, the first and second transistors are both on, such that the source node is driven towards ground;
in the light sleep mode, the first and second transistors are diode-connected, such that the source node is driven towards an intermediate, data-retention voltage level between ground and a power supply voltage level (e.g., VDDC) for the memory device; and
in the shutdown mode, the first and second transistors are both off, such that the source node is driven towards the power supply voltage level.

12. The invention of claim 11, wherein the bias circuitry further comprises:
a first set of transistors (e.g., M2-M5) connected to control gate voltage (e.g., WUT) applied to the first transistor; and
a second set of transistors (e.g., M12-M15) connected to control gate voltage (e.g., WUB) applied to the second transistor.

13. The invention of claim 12, wherein:
the first set of transistors comprises:
an n-type third transistor (e.g., M2) connected between the source node and the gate of the first transistor;
a p-type fourth transistor (e.g., M5) and a p-type fifth transistor (e.g., M4) configured in series between the power supply voltage level and the gate of the first transistor; and
an n-type sixth transistor (e.g., M3) configured between the gate of the first transistor and ground; and
the second set of transistors comprises:
a p-type seventh transistor (e.g., M12) connected between the gate of the second transistor and ground;
an n-type eighth transistor (e.g., M14) and an n-type ninth transistor (e.g., M13) configured in series between the gate of the second transistor and ground; and
a p-type tenth transistor (e.g., M15) configured between the power supply voltage level and the gate of the second transistor.

14. The invention of claim 13, wherein the first and second sets of transistors are configured such that:
a first control signal (e.g., SD) is applied to the gates of the fifth and sixth transistors;
a second control signal (e.g., LSD) is applied to the gates of the third and fourth transistors;
an inverted version of the first control signal (e.g., SDB) is applied to the gates of the eighth and tenth transistors; and
an inverted version of the second control signal (e.g., LSDB) is applied to the gates of the seventh and ninth transistors.

15. A consumer electronics product having a memory device comprising:
an array (e.g., 102) of memory cells having a source node (e.g., VSSC); and
bias circuitry (e.g., 104) configured to control a bias voltage level applied to the source node of the array, wherein the bias circuitry comprises an n-type first transistor (e.g., M1) and a p-type second transistor (e.g., M11) connected in parallel between ground and the source node.

16. The invention of claim 15, wherein the bias circuitry enables the memory device to be selectively configured into any one of:
an active mode in which the array of memory cells can be accessed;
a light sleep mode in which the array of memory cells cannot be accessed, but will retain data previously stored therein; and
a shutdown mode in which the array of memory cells cannot be accessed and will not retain the data previously stored therein.

17. The invention of claim 16, wherein:
in the active mode, the first and second transistors are both on, such that the source node is driven towards ground;
in the light sleep mode, the first and second transistors are diode-connected, such that the source node is driven towards an intermediate, data-retention voltage level between ground and a power supply voltage level (e.g., VDDC) for the memory device; and
in the shutdown mode, the first and second transistors are both off, such that the source node is driven towards the power supply voltage level.

18. The invention of claim 17, wherein the bias circuitry further comprises:
a first set of transistors (e.g., M2-M5) connected to control gate voltage (e.g., WUT) applied to the first transistor; and
a second set of transistors (e.g., M12-M15) connected to control gate voltage (e.g., WUB) applied to the second transistor.

19. The invention of claim 18, wherein:
the first set of transistors comprises:
an n-type third transistor (e.g., M2) connected between the source node and the gate of the first transistor;
a p-type fourth transistor (e.g., M5) and a p-type fifth transistor (e.g., M4) configured in series between the power supply voltage level and the gate of the first transistor; and
an n-type sixth transistor (e.g., M3) configured between the gate of the first transistor and ground; and
the second set of transistors comprises:
a p-type seventh transistor (e.g., M12) connected between the gate of the second transistor and ground;
an n-type eighth transistor (e.g., M14) and an n-type ninth transistor (e.g., M13) configured in series between the gate of the second transistor and ground; and
a p-type tenth transistor (e.g., M15) configured between the power supply voltage level and the gate of the second transistor.

20. The invention of claim 19, wherein the first and second sets of transistors are configured such that:
a first control signal (e.g., SD) is applied to the gates of the fifth and sixth transistors;
a second control signal (e.g., LSD) is applied to the gates of the third and fourth transistors;
an inverted version of the first control signal (e.g., SDB) is applied to the gates of the eighth and tenth transistors; and
an inverted version of the second control signal (e.g., LSDB) is applied to the gates of the seventh and ninth transistors.
